(19) United States
(12) Patent Application Publication
(10) Pub. No.: US 2014/0103281 A1
(43) Pub. Date: Apr. 17, 2014

(54) Resistive Memory Based on TaOx Containing Ru Doping and Method of Preparing the Same

(71) Applicants: Yinyin Lin, Shanghai (CN); Xiaopeng Tian, Shanghai (CN)

(72) Inventors: Yinyin Lin, Shanghai (CN); Xiaopeng Tian, Shanghai (CN)

(73) Assignee: FUDAN UNIVERSITY, Shanghai (CN)

(21) Appl. No.: 13/381,286

(22) PCT Filed: Jul. 6, 2011
(86) PCT No.: PCT/CN2011/001111

§ 371 Date: Dec. 28, 2011

(51) Int. Cl. H01L 45/00

(52) U.S. Cl. CPC H01L 45/146; H01L 45/1608
USPC 257/4; 438/104

(57) ABSTRACT

The present invention pertains to the technical field of semi-conductor memory. More particularly, the invention relates to a resistive memory based on TaOₓ containing Ru doping. The resistive memory comprises an upper electrode, a lower electrode and a TaOₓ based storage medium layer containing Ru doping and provided between the upper electrode and the lower electrode. In the storage medium layer based on TaOₓ containing Ru doping, the position at which conductive filaments are formed in the storage medium layer based on TaOₓ and their number can be effectively controlled through the distributed Ru element, thus avoiding the possibility of random formation. Therefore, the storage performance is more stable and fluctuation of device characteristic parameter is small. Meanwhile, an integration with copper interconnection process at or below 32 nm is made easier.

### FIELD OF THE INVENTION

The present invention pertains to the technical field of semi-conductor memory, and relates to a resistive memory based on metal oxide TaOₓ (2≦x≦3) containing Ru doping and method of preparing the same. More particularly, the invention relates to a resistive memory which uses TaOₓ matrix containing Ru doping as storage medium, and a method of preparing the resistive memory.

### BACKGROUND

Memories have possessed an important position in the market of semiconductors. Due to increasing popularity of portable electronic devices, non-volatile memories have occupied a larger and larger share in the whole market of memory, wherein over 90% shares are held by FLASH. However, due to requirements on storage charge, the floating gate of FLASH cannot be made thinner limitlessly with the development of technology generations. It is reported that the limit of FLASH technology is predicted to be at around 32 nm. Thus, it is urgent to seek a next generation of non-volatile memory having a more superior performance. Recently, resistive switching memory has drawn high degree of attention due to such characteristics as high density, low cost, and being able to break through limitations on development of technical generations. Materials used by resistive switching memory comprises phase-change material, doped SrZrO₃, Ferroelectric material PbZrTiO₃, Ferromagnetic material Pr₁₋ₓCaₓMnO₃, binary metal oxide material, organic material, etc.

Resistive memory switches between a high resistance state (HRS) and a low resistance state (LRS) in a reversible manner under the effect of electrical signal, thereby realizing storage function. The storage medium material used by resistive memory can be various semiconductor metal oxide materials such as Copper oxide, Titanium dioxide, Tungsten oxide, etc.

TaOₓ (1<x≦3) is one of the binary metal oxide materials. The resistance switching characteristic has been reported by Z. Wei et al. in Panasonic Corporation in a document entitled “Highly reliable TaOx ReRAM and Direct Evidence of Redox Reaction Mechanism”, IEDM, 2008. Therefore, TaOₓ can be used as storage medium for resistive memory. As can be seen from the document, the Gibbs free energy ΔG of TaOₓ is small and therefore its switching between LRS and HRS is fast, up to the order of nanosecond. Thus, the problem of applying resistive memory in high speed memory has been solved.

Furthermore, with the development of semiconductor process technology, key sizes are being reduced continuously, and it is necessary that resistive memory technology extends post 45 nm process node. Due to limitations of grain size, corresponding oxides of materials of Cu, W, etc., when used as storage medium, will result in a large leak current, thus increasing power consumption and making it impossible to replace FLASH effectively in the process node of 45 nm and 32 nm. Moreover, at the process node of 32 nm, it is required to reduce the thickness of barrier layer in copper interconnection structure to be 3.6 nm and further increase the ration between depth and width. Traditional Ti/TiN, Ta/TaN, etc., can not meet such requirements. In addition, due to decrease of process sizes, process fluctuation is also more significant, and the problem of electrical characteristic fluctuation of resistive memory based on TaOₓ becomes more prominent.

S. M. Rossnagel, et al., in IBM Corporation points out in a document entitled “Interconnect issues post 45 nm, S. M. Rossnagel” (IEEE INTERNATIONAL ELECTRON DEVICES MEETING 2005, TECHNICAL DIGEST, p 95-97, 2005) that copper diffusion barrier layer material will adopt Ru/TaN complex layer material when post 32 nm process node.

In view of the above prior art, it is necessary to propose a novel resistive type resistance memory.

### SUMMARY OF THE INVENTION

The objective of the invention is to provide a TaOₓ based resistive memory and a method of preparing the same so as to solve the problem of fluctuation of device performance parameters and the problem that prior resistive memory are not easily compatible with copper interconnection process at or below 32 nm process node.

In order to achieve the above objective or other objectives, the invention provides the following technical solution.

According to one aspect of the invention, a TaOₓ based resistive memory is provided comprising an upper electrode, a lower electrode and a TaOₓ based storage medium layer containing Ru doping and provided between the upper electrode and the lower electrode.

According to a preferred technical solution, the storage medium layer is formed by performing annealing diffusion doping of Ru on a TaOₓ thin film layer, wherein 2≦x≦3.

According to another preferred technical solution, the storage medium layer is formed by performing ion implantation doping of Ru on a TaOₓ thin film layer, wherein 2≦x≦3.

Preferably, the thickness range of the storage medium layer is from 1 nm to 200 nm.

According to an embodiment of the TaOₓ based resistive memory of the invention, the TaOₓ based resistive memory further comprises a first dielectric layer located above the lower electrode and apertures formed through the first dielectric layer, the storage medium layer being located at the bottom of the aperture.

According to another embodiment of the TaOₓ based resistive memory of the invention, the lower electrode is copper wire formed in channel in a copper interconnection back-end structure, the storage medium layer being formed at the bottom of copper plug.

According to yet another embodiment of the TaOₓ based resistive memory of the invention, the lower electrode is copper plug in a copper interconnection back-end structure, the storage medium layer being formed at the top of copper plug.

Preferably, the copper interconnection back-end structure is a copper interconnection back-end structure at or below 32 nm process node, wherein copper diffusion barrier layer is Ru/TaN complex layer.

In the storage medium layer, the atomic percentage of Ru element in the storage medium layer is 0.001%-20%.

In the storage medium layer, Ru element exists in the storage medium layer in the form of nano crystal.

The upper electrode is a metal layer of Ta, TaN, Ti, TiN, W, Ni, Al, Co, Cu or Ru, or a complex layer structure formed by any combination of these metal layers.

According to another aspect of the invention, a method of preparing the above TaOₓ based resistive memory is provided, the method comprising the following steps:

(1) pattern-forming a lower electrode;

(2) pattern-forming a storage medium layer based on TaOₓ containing Ru doping on the lower electrode; and

(3) pattern-forming an upper electrode on the storage medium layer.

According to an embodiment of the method of preparing the TaOₓ based resistive memory of the invention, said step (2) comprises the following steps:

(2a) forming a TaOₓ thin film layer on the lower electrode, wherein 2≦x≦3;

(2b) depositing a Ru metal thin film layer or a Ru oxide layer on the TaOₓ thin film layer;

(2c) forming a storage medium layer based on TaOₓ containing Ru doping by annealing diffusion doping.

According to another embodiment of the method of preparing the TaOₓ based resistive memory of the invention, said step (2) comprises the following steps:

(2a′) forming a Ru metal thin film layer or a Ru oxide layer on the lower electrode;

(2b′) depositing a TaOₓ thin film layer on the Ru metal thin film layer, wherein 2≦x≦3;

(2c′) forming a storage medium layer based on TaOₓ containing Ru doping by annealing diffusion doping.

According to yet another embodiment of the method of preparing the TaOₓ based resistive memory of the invention, said step (2) comprises the following steps:

(2A) forming a first Ru metal thin film layer or a first Ru oxide layer on the lower electrode;

(2B) depositing a TaOₓ thin film layer on the first Ru metal thin film layer, wherein 2≦x≦3;

(2C) depositing a second Ru metal thin film layer or a second Ru oxide layer on the TaOₓ thin film layer;

(2D) forming a storage medium layer based on TaOₓ containing Ru doping by annealing diffusion doping.

According to still another embodiment of the method of preparing the TaOₓ based resistive memory of the invention, said step (2) comprises the following steps:

(2A′) forming a first TaOₓ thin film layer on the lower electrode, wherein 2≦x≦3;

(2B′) depositing a Ru metal thin film layer or a Ru oxide layer on the TaOₓ thin film layer;

(2C′) forming a second TaOₓ thin film layer on the Ru metal thin film layer;

(2D′) forming a storage medium layer based on TaOₓ containing Ru doping by annealing diffusion doping.

Preferably, the thickness range of the Ru metal thin film layer is from about 0.3nm to about 150 nm; the thickness range of the Ru oxide layer is from about 0.3 nm to about 10 nm. The thickness range of the TaOₓ thin film layer is from about 1 nm to about 200 nm.

The TaOₓ thin film layer is formed by oxidizing Ta metal; said oxidizing is an oxidizing in oxygen containing gas at high temperature, an oxidizing in oxygen plasma at high temperature or wet oxidizing.

The Ru oxide layer is RuO₂; when in annealing, a temperature range between 400° C. to 900° C. is selected, wherein the following decomposition reaction occurs on RuO₂:RuO₂→Ru+O₂

The technical effect brought about by the invention lies in that in the storage medium layer based on TaOₓ containing Ru doping, the position at which conductive filaments are formed in the storage medium layer based on TaOₓ and their number can be effectively controlled through the distributed Ru element, thus avoiding the possibility of random formation. Therefore, the storage performance is made more stable and fluctuation of device characteristic parameter is small. Meanwhile, an integration with copper interconnection process at or below 32 nm is made easier.

### BRIEF DESCRIPTION OF THE DRAWINGS

The above and other objectives and advantages of the invention will become more fully apparent from the following detailed description with reference to accompanying drawings, wherein identical or similar elements are denoted by identical signs.

FIG. 1 is a schematic structure view of a TaOₓ based resistive memory according to a first embodiment of the invention;

FIG. 2 is a schematic view explaining functional model of the TaOₓ based resistive memory shown in FIG. 1;

FIG. 3 is a schematic structure view of a TaOₓ based resistive memory according to a second embodiment of the invention;

FIG. 4 is a schematic view showing the first embodiment of the method of preparing the TaOₓ based resistive memory shown in FIG. 3;

FIG. 5 is a schematic view showing the second embodiment of the method of preparing the TaOₓ based resistive memory shown in FIG. 3;

FIG. 6 is a schematic view showing the third embodiment of the method of preparing the TaOₓ based resistive memory shown in FIG. 3;

FIG. 7 is a schematic view showing the fourth embodiment of the method of preparing the TaOₓ based resistive memory shown in FIG. 3;

FIGS. 8 to 11 are schematic structure views showing dope forming (TaOₓ:Ru) storage medium layer with Ru oxide layer as diffusion doping layer;

FIG. 12 is a schematic principal view of annealing diffusion with Ru oxide layer as diffusion doping layer;

FIG. 13 is a schematic structure view of a TaOₓ based resistive memory according to a third embodiment of the invention;

FIG. 14 is a schematic structure view of a TaOₓ based resistive memory according to a fourth embodiment of the invention.

### DETAILED DESCRIPTION OF THE INVENTION

The invention will be more fully described in exemplary embodiments with reference to accompanying drawings hereinafter. While the invention provides preferred embodiments, it is not intended that the invention is limited to the described embodiments. For clarity, the thicknesses of layers and regions have been exaggerated in the drawings. However, it should not be construed that these schematic views strictly reflect proportional relationship between geometrical dimensions.

Herein, the reference views are schematic views of idealized embodiments of the invention. The illustrated embodiments of the invention should not be considered to be merely limited to the particular shapes of regions shown in the drawings. Rather, the invention comprises various shapes that can be derived, such as deviations caused during manufacture. For example, a profile obtained by dry etching generally has such characteristics of being curved or rounded, however, they are all represented by a rectangle in the drawings of embodiments of the invention. The illustrations in the drawings are schematic and should not be construed as limiting the scope of invention.

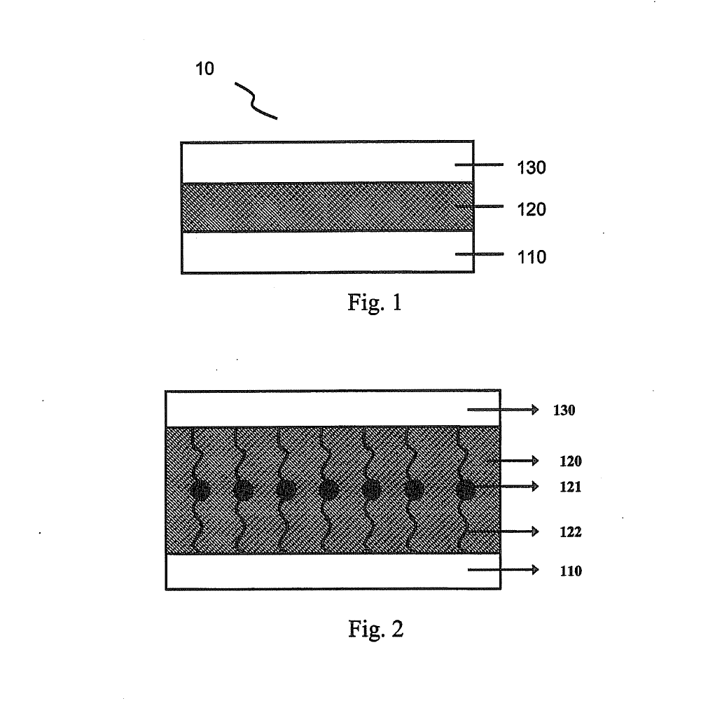

FIG. 1 is a schematic structure view of a TaOₓ based resistive memory according to a first embodiment of the invention. As shown in FIG. 1, the resistive memory 10 comprises an upper electrode 130, a lower electrode 110 and a storage medium layer 120 of TaOₓ containing Ru doping (TaOₓ:Ru) provided between the upper electrode and the lower electrode, wherein 2≦x≦3. The amount of doped Ru can be selected according to specific requirements on storage characteristics. Specifically, according to a preferred scope of doped amount, the atomic percentage of Ru element in the storage medium layer is 0.001%-20%, such as 0.5% or 2%. The form in which Ru element exists in the storage medium layer 120 is not restricted by the invention. For example, Ru can exist in the form of separate Ru element, or in the form of RuO or RuO₂, or in the form of any combination of the above three forms. In structure, Ru, RuO or RuO₂ can exist in the form of nano crystal. Moreover, oxygen element can be distributed in the storage medium layer 120 in an even or uneven manner. For example, it can be distributed in such a way that it decreases gradually from top to bottom in the storage medium layer 120. The specific content of oxygen element and specific distribution form are related to the method of oxidizing and process conditions. The thickness of the storage medium layer 120 is not restricted by the invention. Preferably, the thickness range can be from about 1 nm to about 200 nm.

An electrical signal, such as a voltage pulse signal and a current pulse signal, is applied between the upper electrode 130 and the lower electrode 110. (TaOₓ:Ru) storage medium layer 120 can be switched between a high resistance state and a low resistance state, wherein the switch from high resistance state to low resistance state is defined as Set operation, and the switch from low resistance state to high resistance state is defined as Reset operation. According to the principle of resistive memory, the switch of storage medium layer between a high resistance state and a low resistance state is realized by a formation and disconnect of filament in the storage medium layer. After TaOₓ is doped with Ru, the storage characteristic of device is more stable as compared with prior resistive memory in which TaOₓ is used as storage medium layer. For example, the distribution in high resistance state or low resistance state is more even. Therefore, the resistive memory 10 can effectively prevent fluctuation of characteristic parameters of device

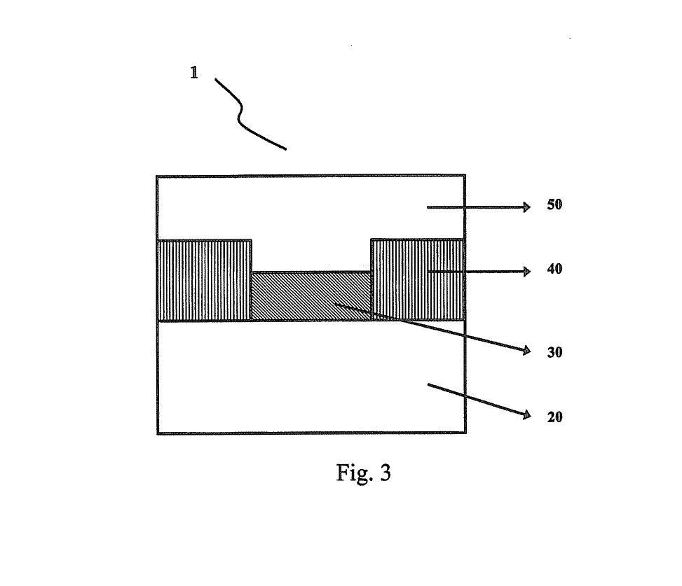

FIG. 2 is a schematic view explaining functional model of the TaOₓ based resistive memory shown in FIG. 1. As shown in FIG. 2, the resistive memory is in the low resistance state. Several conductive filaments 122 are formed in the (TaOₓ:Ru) storage medium layer 120. The conductive filaments 122 have a relatively lower resistance, thus conducting the upper electrode 130 and the lower electrode. The filaments are typically formed by oxygen vacancies. After Ru is doped, the conductive Ru or Ru oxide are distributed in the storage medium layer 120. When the Set operation is performed, filaments are more prone to be formed at positions where Ru element is distributed, thus effectively controlling the positions where conductive filaments 122 are formed and the number thereof and avoiding the possibility of random formation. Therefore, the storage characteristic can be made more stable. In the illustrated embodiment, each filament is distributed with doped Ru 121 which exists in the form of nano crystal.

FIG. 3 is a schematic structure view of a TaOₓ based resistive memory according to a second embodiment of the invention. Again, the resistive memory 10 comprises a lower electrode 20, an upper electrode 50, and a storage medium layer 30 of TaOₓ containing Ru doping (TaOₓ:Ru) formed between the upper electrode 50 and the lower electrode 20. This embodiment differs from the embodiment shown in FIG. 1 in that it further comprises a dielectric layer 40 above the lower electrode 20 and apertures formed through the dielectric layer 40, and the (TaOₓ:Ru) storage medium layer 30 is formed at the bottom the apertures of the dielectric layer 40. Therefore, the area of (TaOₓ:Ru) storage medium layer 30 is defined by the apertures of the dielectric layer. In order to facilitate integrating with copper interconnection process, it is preferred that the lower electrode 20 is selected as copper metal layer, such as copper wire.

The method process of preparing TaOₓ based resistive memory will be further described in combination with the embodiment shown in FIG. 3 hereinafter.

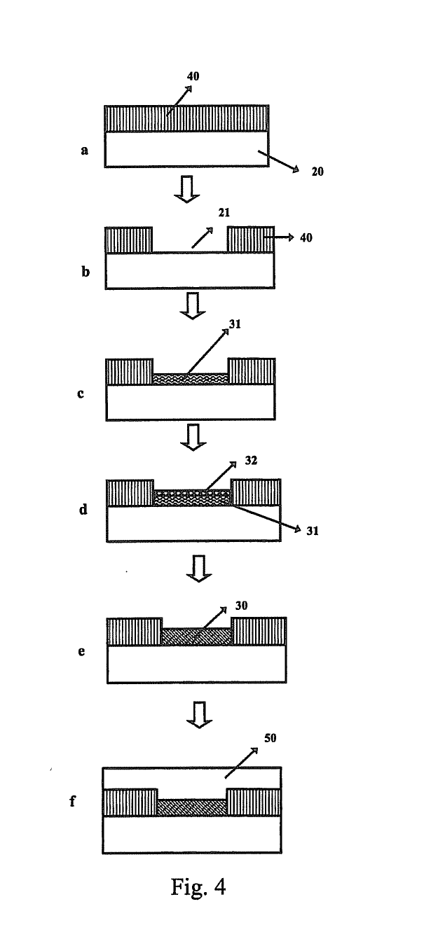

FIG. 4 is a schematic view showing the first embodiment of the method of preparing the TaOₓ based resistive memory shown in FIG. 3.

As shown in FIG. 4a, at step S10, a dielectric layer 40 is deposited on the lower electrode 20; the lower electrode 20 can be various conductive metal layer such as copper metal layer or Ta metal layer. The thickness of the dielectric layer 40 is selected and determined according to the thickness of the storage medium layer. The material of the dielectric layer 40 can be SiO₂, Si₃N₄, SiOCH, FSG (F doped silicon oxide) HSQ (H doped silicon oxide) or a complex material thereof, or other materials which function as well. The dielectric layer 40 can be formed by sputtering, CVD deposition, etc.

As shown in FIG. 4b, at step S20, apertures 21 are formed on the dielectric layer 40 by pattern-etching; the area of apertures 21 is selected and determined according to the area of storage medium layer intended to be formed. The apertures 21 can be formed by conventional lithography etching process.

As shown in FIG. 4; at step S30, a TaOₓ thin film layer 31 is formed at the bottom of the apertures. The TaOₓ thin film layer is mainly formed by the two following methods: (1) direct depositing; (2) oxidizing Ta metal. When the first method is employed, for example, the TaOₓ thin film layer can be formed by reactive sputter deposition in oxygen gas atmosphere. The process conditions of sputter (e.g., flow of oxygen gas, pressure, temperature, etc) determine the ratio of specific components of the TaOₓ thin film layer. Those skilled in the art, when enlightened by this application, can determine specific process conditions experimentally. When the second method is employed, there exists two different procedures to form the TaOₓ thin film layer: (a) the lower electrode 20 uses Ta metal, and the TaOₓ thin film layer 31 is formed by oxidizing part of Ta metal with the dielectric layer 40 as mask; (b) a Ta metal thin film layer is deposited first and the TaOₓ thin film layer 31 is then formed by oxidizing Ta metal thin film layer, wherein the methods of oxidizing main includes: (1) oxidizing in gas containing oxygen at high temperature; (2) oxidizing in oxygen plasma at high temperature; (3) wet oxidizing. Taking the oxidizing method in (1) as an example, by exposing Ta metal thin film layer in the apertures 21 to oxygen containing gas at a certain high temperature (300° C.-600° C.) condition, a chemical reaction will occur between the Ta metal and the gas and a TaOₓ compound layer will be produces by oxidizing. In this embodiment, the constant gas pressure during the chemical reaction is smaller than 20 Torr. In the produced TaOₓ compound layer, 2≦x≦3, the stoichiometric ratio of oxygen and Ta is relevant to the process parameters during formation, such as gas flow, temperature, duration etc, and the ratio of oxygen and Ta in the TaOₓ compound layer is not necessarily entirely even. In this embodiment, since Ta on the surface is more easily bonded to gas containing oxygen, the closer it is to the lower electrode 20 in the TaOₓ compound layer, the higher the ratio of Ta and oxygen is. The thickness of the TaOₓ thin film layer 31 is not restricted by the invention. Preferably, the thickness range can be from about 1 nm to about 40 nm, e.g., 5 nm.

As shown in FIG. 4d, at step S40, a Ru metal thin film layer 32 is deposited on the TaOₓ thin film layer 31. The Ru metal thin film layer 32 is mainly used for diffusion doping. Therefore, a thinner thickness is selected for the Ru metal thin film layer 32. The thickness range of the Ru metal thin film layer 32 can be from about 0.3 nm to about 10 nm. For example, it can be selected as him or 2 nm. The Ru metal thin film layer 32 can be formed by such processes as sputter, ALD (atomic layer deposition), etc.

As shown in FIG. 4e, at step S50, the (TaOₓ:Ru) storage medium layer 30 is formed by annealing diffusion doping. In this embodiment, Ru at the surface layer can be diffused to the TaOₓ thin film layer by annealing in certain conditions, so that the (TaOₓ : Ru) storage medium layer 30 is formed. Specifically, a quick annealing treatment in vacuum condition can be selected, wherein the annealing temperature is 300° C.-700° C. and the annealing duration is 10-30 minutes. Ru atoms diffuse into the TaOₓ thin film layer and exist in the storage medium layer 30 in the form of Ru atoms or RuOz (1≦z≦2) oxides.

As shown in FIG. 4f, at step S60, the upper electrode 50 is formed by patterning. The upper electrode 50 and the lower electrode 30 can be of a single layer structure, and can be metal materials such as Ta, TaN, Ti, TiN, W, Ni, Al, Co, Cu or Ru, or a complex layer structure formed by any combination of these single layer structures. For example, when the thickness of the Ru metal thin film layer 32 is thick and Ru does not totally diffuse, the remaining Ru metal (not shown) can be used as a portion of the upper electrode 50.

Hitherto, the TaOₓ based resistive memory shown in FIG. 3 is substantially formed. The preparation method shown in FIG. 4 has many modifications, especially on the structure before forming the (TaOₓ:Ru) storage medium layer 30 by doping. There can be many modifications on the positions of Ru metal thin film layer and TaOₓ thin film layer, which will be described respectively hereinafter.

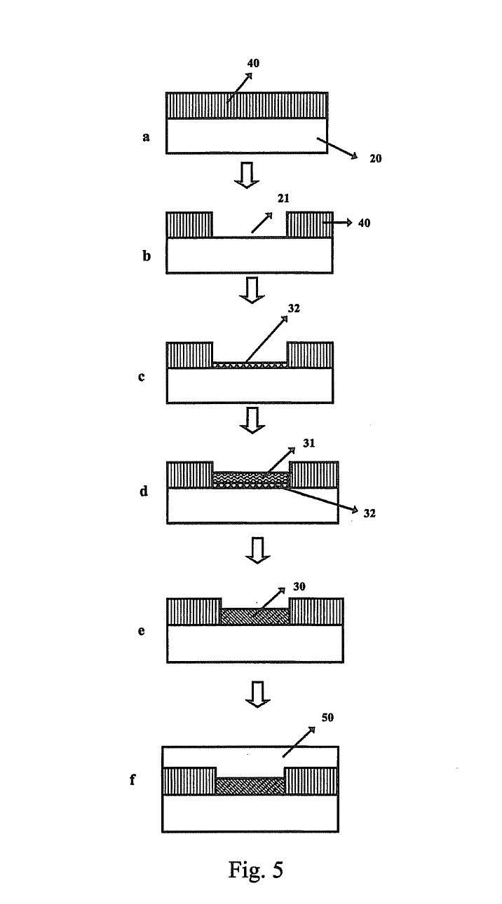

FIG. 5 is a schematic view showing the second embodiment of the method of preparing the TaOₓ based resistive memory shown in FIG. 3. As compared with the embodiment shown in FIG. 4, the embodiment shown in FIG. 5 is different in that it performs step S40 first before performing step S50. As shown in FIG. 5c, the Ru metal thin film layer 32 is formed at the bottom of the apertures. Then, as shown in FIG. 5d, the TaOₓ thin film layer 31 is deposited on the Ru metal thin film layer 32. During annealing diffusion, Ru is diffusion doped upwardly from the bottom. Other steps are substantially the same as those described above and will not be discussed repeatedly.

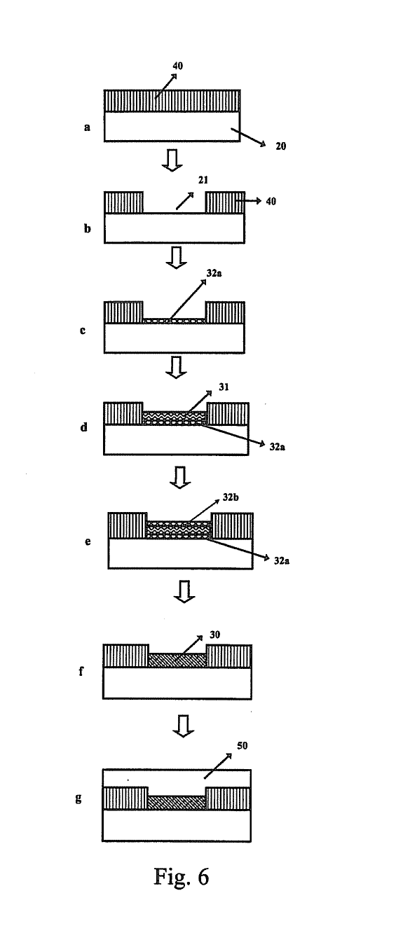

FIG. 6 is a schematic view showing the third embodiment of the method of preparing the TaOₓ based resistive memory shown in FIG. 3. As compared with the embodiment shown in FIG. 5, the embodiment shown in FIG. 6 is different in that a Ru metal thin film layer 32b and 32a are formed both above and below the TaOₓ thin film layer 32 respectively, and Ru is diffusion doped towards the TaOₓ thin film layer 31 simultaneously from the bottom and top of the TaOₓ thin film layer 31. As shown in FIG. 6c, a Ru metal thin film layer 32a is formed at the bottom of the apertures; as further shown in FIG. 6d, a TaOₓ thin film layer 31 is deposited on the Ru metal thin film layer 32a; then, as shown in FIG. 6e, the Ru metal thin film layer 32b is deposited on the TaOₓ thin film layer 31. Other steps are substantially the same as those described above with respect to FIG. 4 and will not be discussed repeatedly.

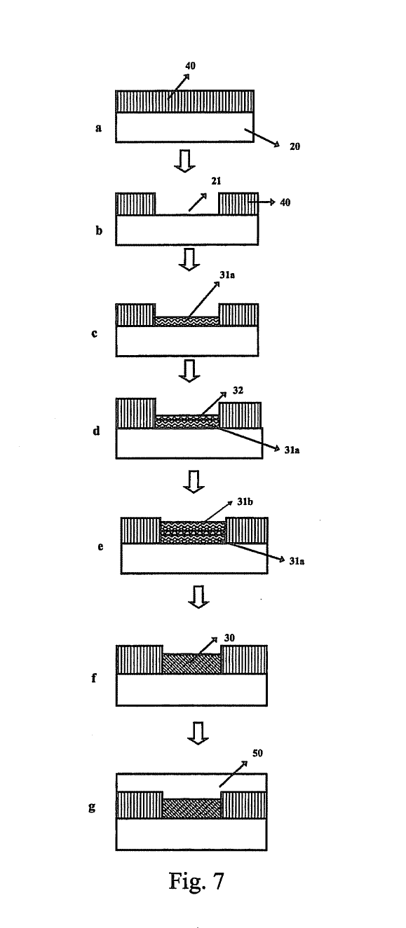

FIG. 7 is a schematic view showing the fourth embodiment of the method of preparing the TaOₓ based resistive memory shown in FIG. 3. As compared with the embodiment shown in FIG. 4, the embodiment shown in FIG. 7 is different in that a Ru metal thin film layer 32 is formed between two TaOₓ thin film layers 31a and 31b, and Ru is diffusion doped from the bottom of the TaOₓ thin film layer 31a and the top of the TaOₓ thin film layer 31b respectively. As shown in FIG. 7c, the TaOₓ thin film layer 31a is formed at the bottom of the apertures; as further shown in FIG. 7d, the Ru metal thin film layer 32 is deposited on the TaOₓ thin film layer 31a; then, as shown in FIG. 7e, another TaOₓ thin film layer 31b is formed on the Ru metal thin film layer 32. Other steps are substantially the same as those described above with respect to FIG. 4 and will not be discussed repeatedly.

The methods of heat diffusion doping Ru are specifically described in the above embodiments of preparation methods. However, the (TaOₓ:Ru) storage medium layer 30 shown in FIG. 4e can also be formed by performing Ru ion implantation doping on the TaOₓ thin film layer 31 shown in FIG. 4c.

During the course of annealing diffusion doping Ru, the invention is not merely limited to proposing the methods shown in FIGS. 4-7 for performing diffusion doping using Ru metal thin film layer. A method which uses conductive Ru oxide layer in place of Ru metal thin film layer as the diffusion doping layer is further proposed.

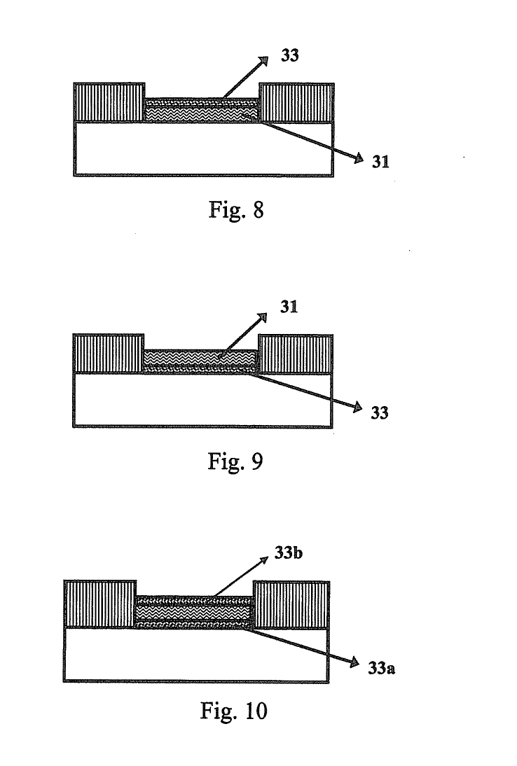

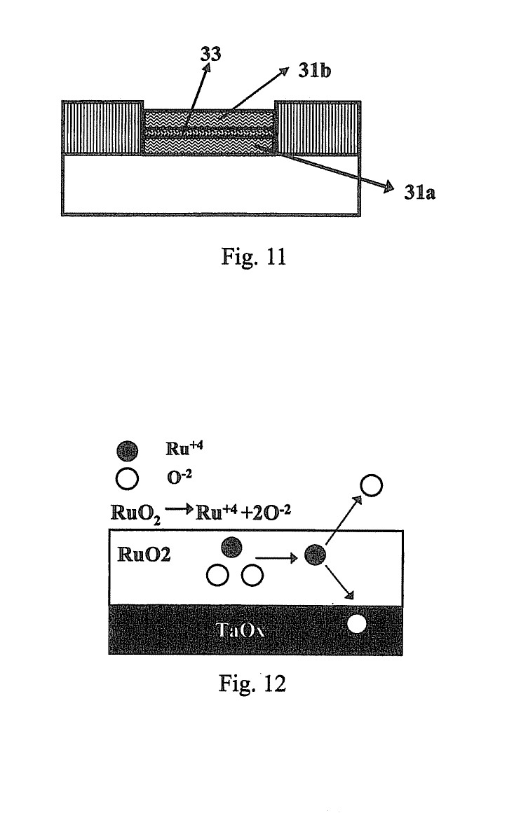

FIGS. 8 to 11 are schematic structure views showing dope forming (TaOₓ:Ru) storage medium layer with Ru oxide layer as diffusion doping layer, wherein the structure embodiment shown in FIG. 8 is used to replace the structure of FIG. 4d. As shown in FIG. 8, Ru oxide layer 33 is used to replace Ru metal thin film layer 32. The structure embodiment shown in FIG. 9 is used to replace the structure of FIG. 5d. As shown in FIG. 9, Ru oxide layer 33 is used to replace Ru metal thin film layer 32. The structure embodiment shown in FIG. 10 is used to replace the structure of FIG. 6e. As shown in FIG. 10, Ru oxide layers 33a and 33b are used to replace Ru metal thin film layers 32a and 32b respectively. The structure embodiment shown in FIG. 11 is used to replace the structure of FIG. 7e. As shown in FIG. 11, Ru oxide layer 33 is used to replace Ru metal thin film layer 32. In the above exemplary structures, the thickness range of Ru oxide layer is preferably from about 0.3 nm to about 10 nm. For example, it can be selected to be 1 nm or 2 nm. The Ru oxide layer can be formed by thin film deposition methods such as reactive sputtering, etc. Preferably, the Ru oxide layer is RuO₂. When Ru oxide layer is used as diffusion doping layer, those skilled in the art can, during the process of annealing diffusion, select annealing conditions that are different from the method process of the embodiment shown in FIG. 4 as required. For example, the annealing temperature can be selected to be 400° C.-900° C., and the annealing duration can be selected to be 30 seconds to 30 minutes. It is noted that for the structure shown in FIG. 10, such a structure can be employed in other embodiments where one layer is Ru metal thin film layer while the other layer is Ru oxide layer, i.e., Ru metal thin film layer and Ru oxide layer simultaneously serve as diffusion doping layer.

FIG. 12 is a schematic principal view of annealing diffusion with Ru oxide layer as diffusion doping layer. As shown in FIG. 12, a decomposition reaction: RuO₂→Ru+O₂ will occur on RuO₂ at a certain temperature, thus producing RuO or Ru nano crystal which diffuses towards TaOₓ thin film layer. If the decomposition is incomplete, Ru can also exist in the form of RuO₂ nano crystal. It is further noted that, all of RuO₂, RuO and Ru are conductive and their resistivities do not differ much from each other. Therefore, even if the decomposition of RuO₂ is incomplete and only RuO or RuO₂ nano crystals exist in TaOₓ, conductive filaments can be stabilized so that conductive filaments are distributed around RuO or RuO₂ nano crystals. In addition, O⁻² produced after decomposition of RuO₂ are diffused into the TaOₓ thin film layer and atom-bonded with Ta atoms so that oxygen vacancies are filled in. Therefore, defect concentration in original TaOₓ storage medium layer is reduced, resistance in initial resistance state and resistance in low resistance state of (TaOₓ:Ru) storage medium layer are effectively improved, whereby as compared with the method show in FIG. 4, power consumption of device can be more reduced.

The (TaOₓ:Ru) storage medium layer formed by the above described method contains tow metal elements, Ta and Ru. According to the prior art, in a copper interconnection structure at or below 32 nm process node, the diffusion barrier layer of copper will employ Ru/TaN complex layer material, which also contains metal elements of Ru and Ta. Therefore, when the resistive memory is integrated with a copper interconnection back-end process structure, no new elements will be introduced. Therefore, process risk is low and the resistive memory can be easily integrated with copper interconnection back-end process at or below 32 nm process node.

Hereinafter, the embodiment of TaOₓ based resistive memory integrated with a copper interconnection back-end structure will be further described.

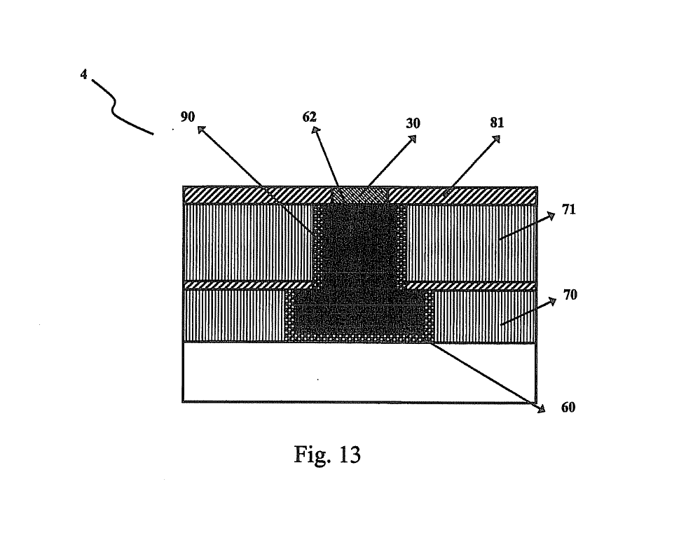

FIG. 13 is a schematic structure view of a TaOₓ based resistive memory according to a third embodiment of the invention. In this embodiment, the TaOₓ based resistive memory 4 can be integrated with a copper interconnection back-end process. The lower electrode of the TaOₓ based resistive memory 4 is a copper plug 62 in the copper interconnection, and the (TaOₓ:Ru) storage medium layer 30 is formed at the top of the copper plug 62. The TaOₓ based resistive memory 4 can be formed by the following method process.

With reference to FIG. 13, copper wire 60 and copper plug 62 on the copper wire 60 are formed by conventional Damascene process or dual Damascene process. Then, a cap layer 81 is formed on the copper plug 62 and inter-layer dielectric layer 71. Thereafter, the cap layer 81 is pattern-etched so as to open the top of the copper plug 62. Therefore, the (TaOₓ:Ru) storage medium layer 30 can be formed in the hole of open copper plug according to the methods of various embodiments described above. Further, an upper electrode (not shown in FIG. 13) can also be formed on the (TaOₓ:Ru) storage medium layer 30.

Preferably, the copper interconnection structure is a copper interconnection structure at or below 32 nm process node, wherein the diffusion barrier layer 90 employs Ru/TaN complex layer.

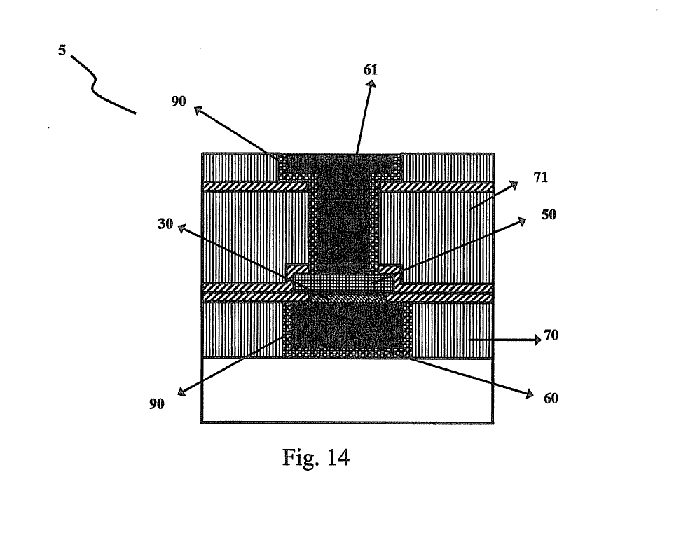

FIG. 14 is a schematic structure view of a TaOₓ based resistive memory according to a fourth embodiment of the invention. In this embodiment, the TaOₓ based resistive memory 5 can be integrated with a copper interconnection back-end process. The lower electrode of the TaOₓ based resistive memory 5 is copper wire 60 in the copper interconnection. The (TaOₓ:Ru) storage medium layer 30 is formed at the bottom of the copper plug 62. In this embodiment, an upper electrode 50 formed between the (TaOₓ:Ru) storage medium layer 30 and the copper plug 61 is further included. Also, it is preferred that the copper interconnection structure is a copper interconnection structure at or below 32 nm process node, wherein the diffusion barrier layer 90 employs Ru/TaN complex layer.

The above embodiments mainly describe the resistive memories of the invention and methods of preparing the same. Though some of the embodiments of the invention have been described, those skilled in the art will understand that the invention can be implemented in many other forms without departing from its spirit and scope. Therefore, the illustrated examples and embodiments should be considered as schematic rather than being limiting. The invention can cover various modifications and substitutes without departing from the spirit and scope of the invention defined by appended claims.

1. A TaOₓ based resistive memory, comprising an upper electrode, a lower electrode characterized in that the TaOₓ based resistive memory further comprises a TaOₓ based storage medium layer containing Ru doping and provided between the upper electrode and the lower electrode.

2. The TaOₓ based resistive memory according to claim 1, characterized in that the storage medium layer is formed by performing annealing diffusion doping of Ru on a TaOₓ thin film layer or performing ion implantation doping of Ru on a TaOₓ thin film layer, wherein 2≦x≦3.

3. The TaOₓ based resistive memory according to claim 1 or 2, characterized in that the thickness of the storage medium layer is from 1 nm to 200 nm.

4. The TaOₓ based resistive memory according to claim 1, characterized in that the TaOₓ based resistive memory further comprises a first dielectric layer located above the lower electrode and apertures formed through the first dielectric layer, the storage medium layer being located at the bottom of the aperture.

5. The TaOₓ based resistive memory according to claim 1, characterized in that the lower electrode is copper wire formed in trench of copper interconnection back-end structure, the storage medium layer being formed at the bottom of copper plug; or the lower electrode is copper plug in a copper interconnection back-end structure, the storage medium layer being formed at the top of copper plug.

6. The TaOₓ based resistive memory according to claim 5, characterized in that the copper interconnection back-end structure is a copper interconnection back-end structure at or below 32 nm process node, wherein copper diffusion barrier layer is Ru/TaN complex layer.

7. The TaOₓ based resistive memory according to claim 1, characterized in that in the storage medium layer, the atomic percentage of Ru element in the storage medium layer is 0.001%-20%.

8. The TaOₓ based resistive memory according to claim 1, characterized in that in the storage medium layer, Ru element exists in the storage medium layer in the form of nano crystal.

9. The TaOₓ based resistive memory according to claim 1, characterized in that the upper electrode is a metal layer of Ta, TaN, Ti, TiN, W, Ni, Al, Co, Cu or Ru, or a complex layer structure formed by any combination of these metal layers.

10. A method of preparing the TaOₓ based resistive memory according to claim 1, characterized in that the method comprises the following steps:
(1) pattern-forming a lower electrode;
(2) pattern-forming a storage medium layer based on TaOₓ containing Ru doping on the lower electrode; and
(3) pattern-forming an upper electrode on the storage medium layer.

11. The method of preparing according to claim 10, characterized in that said step (2) comprises the following steps:
(2a) forming a TaOₓ thin film layer on the lower electrode, wherein 2≦x≦3;
(2b) depositing a Ru metal thin film layer or a Ru oxide layer on the TaOₓ thin film layer;
(2c) forming a storage medium layer based on TaOₛ containing Ru doping by annealing diffusion doping;
or said step (2) comprises the following steps:
(2a′) forming a Ru metal thin film layer or a Ru oxide layer on the lower electrode;
(2b′) depositing a TaOₓ thin film layer on the Ru metal thin film layer, wherein 2≦x≦3;
(2c′) forming a storage medium layer based on TaOₓ containing Ru doping by annealing diffusion doping;
or said step (2) comprises the following steps:
(2A) forming a first Ru metal thin film layer or a first Ru oxide layer on the lower electrode;
(2B) depositing a TaOₓ thin film layer on the first Ru metal thin film layer, wherein 2≦x≦3;
(2C) depositing a second Ru metal thin film layer or a second Ru oxide layer on the TaOₓ thin film layer;
(2D) forming a storage medium layer based on TaOₓ containing Ru doping by annealing diffusion doping;
or said step (2) comprises the following steps:
(2A′) forming a first TaOₓ thin film layer on the lower electrode, wherein 2≦x≦3;
(2B′) depositing a Ru metal thin film layer or a Ru oxide layer on the TaOₓ thin film layer;
(2C′) forming a second TaOₓ thin film layer on the Ru metal thin film layer;
(2D′) forming a storage medium layer based on TaOₓ containing Ru doping by annealing diffusion doping.

12. The method of preparing according to claim 11, characterized in that the thickness range of the Ru metal thin film layer is from about 0.3 nm to about 150 nm; the thickness range of the Ru oxide layer is from 0.3 nm to 10 nm.

13. The method of preparing according to claim 11, characterized in that the thickness range of the TaOₓ thin film layer is from 1 nm to 200 nm.

14. The method of preparing according to claim 11, characterized in that the TaOₓ thin film layer is formed by oxidizing Ta metal.

15. The method of preparing according to claim 11, characterized in that the Ru oxide layer is RuO₂; when in annealing, a temperature range between 400° C. to 900° C. is selected, wherein the following decomposition reaction occurs on RuO₂:RUO₂→Ru+O₂.
